(19) United States
(12) Patent Application Publication
(10) Pub. No.: US 2014/0159183 A1
(43) Pub. Date: Jun. 12, 2014

(54) HIGH-EFFICIENCY BANDWIDTH PRODUCT GERMANIUM PHOTODETECTOR

(71) Applicant: NATIONAL TSING HUA UNIVERSITY, Hsinchu City (TW)

(72) Inventor: Yun-Chung Na, Hsinchu City (TW)

(73) Assignee: NATIONAL TSING HUA UNIVERSITY, Hsinchu City (TW)

(21) Appl. No.: 13/709,209

(22) Filed: Dec. 10, 2012

(51) Int. Cl. H01L 31/0232

(52) U.S. Cl. CPC H01L 31/0232
USPC 257/432

(57) ABSTRACT

A high-efficiency bandwidth product germanium photodetector includes a silicon substrate having an opening-down three-sided groove formed by etching; a metallic reflective mirror layer formed by plating along an internal periphery of the opening-down three-sided groove of the silicon substrate; a light absorbent layer between the metallic reflective mirror layer and a dielectric reflective mirror layer. The light absorbent layer can be p-i-n type or other types. By the use of the critical coupling of resonant cavity, all the incident lights can be completely obstructed in the cavity between the metallic reflective mirror layer and the dielectric reflective mirror layer to reach a critical coupling which means 100% absorption efficiency can be achieved without light leakage. Thus on the basis of the critical coupling, the trade-off between bandwidth and efficiency can be broken through to reach high responsivity and high bandwidth up to 50 GHz by decreasing the germanium layer thickness without sacrificing the light-switch-to-electro absorption efficiency.

### BACKGROUND OF THE INVENTION

1. Field of the Invention

The present invention relates to a photodetector, particularly to a high-efficiency bandwidth product germanium photodetector, and more particularly to a high-efficiency bandwidth product germanium photodetector in which all incident lights can be completely locked in the cavity between the metallic reflective mirror layer and the dielectric reflective mirror layer by means of upper and lower reflective layers to reach a critical coupling which means 100% absorption efficiency can be achieved without light leakage, and therefore, on the basis of the critical coupling, the trade-off between bandwidth and efficiency can be broken through decreasing the germanium layer thickness without sacrificing the light-switch-to-electro absorption efficiency.

2. Description of Related Art

Current technology for manufacturing photodetectors on the market has been well developed and used in a variety of optical communication products. When a semiconductor photodetector is exposed to a light source, the light energy is absorbed and converted into an electronic signal and a current is generated for output. Thereby it can be used in optical communication and optical detection.

The optical journal “OPTICS EXPRESS” 16479, 2010, titled “high-sensitivity 10 Gbps Ge-on-Si photoreceiver operating at λ˜1.55 μm, Jiho Joo, disclosed a high-sensitivity optical receiver based on a vertical plane irradiation of 100% Ge-on-Si photodetector.

A PIN photodetector having countertop of 90 μm in diameter has −3 dB bandwidth of 7.7 GHz, and responsivity of 0.9 A/W corresponding to an 72% external quantum efficiency at λ˜1.55 μm. BER of a TO-can package germanium optical receiver at 10 Gbps data rate of 10⁻¹² shows the sensitivity of −18.5 dBm. The results prove that the Ge-on-Si optical receiver offers 100% cost-effective effect, and capability of replacing the III-V counterparts for optical communication. However, even though this technology has higher responsiveness, it still disadvantageously has low bandwidth.

Johann Osmond, 40 Gb/s surface-illuminated Ge-on-Si photodetectors, (APPLIED PHYSICS LETTERS 95, 151116, 2009), reported a germanium photodetector in which single chip integrated on a silicon substrate and operating in the C and L-band surface is irradiated. A photodetector with bias germanium desktop has a diameter ranging from 10 to 25 μm, and the response of 0.08˜0.21 A/W at wavelength of 1.5 μm. −3 dB cutoff frequency of up to 49 GHz is obtained at 5V reverse bias and wavelength of 1.5 μm. Furthermore, an eye diagram with display in 40 Gbit/s is used. Such a conventional PIN photodetector with a 15 μm-diameter countertops has −3 dB bandwidth of 40 GHz, and is responsive corresponding to 10% external quantum efficiency of 0.12 A/W at λ˜1.5 μm. Even though it makes the bandwidth improved, the responsivity becomes poor.

In addition, in the market of high-speed optic fiber network, a vertical cavity surface emitting laser (VCSEL) has used multilayer distributed Bragg reflectors (DBRs) upper and lower a light-emitting layer. However, VCSEL is a light-emitting element whereas the photodetector is a light absorption component which has different operating principle from the VCSEL. The DBR, made of non-metallic material, in the VCSEL is used as a mirror on both sides of a resonant cavity. The materials and the structural designs are very different from one another.

Furthermore, an optical coupling device in which a conventional photodetector can be integrated with is shown in FIG. 4. A bottom of a substrate 300 is etched an inclined surface which is then plated with a first total reflection surface 353, while the other inclined surface being plated with a second total reflection surface 354. When an incident light go to an antireflection film 352 and then reach the second total reflection surface 353, the light is reflected into a photodetector 360. A portion of the light is absorbed by the photodetector 360, while another portion of the light is reflected to the second total reflection surface 354 and then reflected to a third total reflection surface 351. The light from the third total reflection surface 351 is then reflected back to the second total reflection surface 354, and finally reflected to the photodetector 360. All the incident lights are locked in this region. However, this photodetector 360 is silent in thickness range. Therefore it may be made very thin or may also very thick and the optical reflection occurs only twice in this device. If it is very thin, not all of the light will be absorbed and the light is turning back along the original path resulting in light leakage. In such a device, the reflective surface at the bottom of the substrate 300 not only cannot be used as a planar structure which significantly limits the structural design, but also the inclined surface at the bottom of the substrate 300 works only at a certain angle for effective reflection. If the angle is not accurately calculated, or slight deviation of the manufacturing process occurs, the path of the light reflection will different, adversely affecting the light absorption efficiency. Therefore, the conventional structure cannot meet the requirements of no light leakage for the users in actual use.

### SUMMARY OF THE INVENTION

A main purpose of this invention is to provide a high-efficiency bandwidth product germanium photodetector which overcomes the shortages in the prior art and all incident lights can be completely locked in the cavity between the metallic reflective mirror layer and the dielectric reflective mirror layer by means of upper and lower reflective layers to reach a critical coupling which means 100% absorption efficiency can be achieved without light leakage. Thus on the basis of the critical coupling, the trade-off between bandwidth and efficiency can be broken through decreasing the germanium layer thickness without sacrificing the light-switch-to-electro absorption efficiency.

In order to achieve the above and other objectives, the high-efficiency bandwidth product germanium photodetector of the invention includes
a silicon substrate, having an opening-down three-sided groove;
a metallic reflective mirror layer; disposed along an internal periphery of the opening-down three-sided groove of the silicon substrate, and therefore having the opening-down three-sided structure conform to the opening-down three-sided groove;
a light absorbent layer, disposed on the metallic reflective mirror layer and having a pin structure which includes a p-type amorphous silicon layer (a-Si), an i-type germanium layer and an n-type epitaxial silicon layer (Epi-Si); and
a dielectric reflective mirror layer, disposed on the light absorbent layer, wherein with the use of the metal reflective mirror layer, a resonator structure which allows the light to reflect several times is formed;
wherein the reflectance ratio of the dielectric reflective mirror layer to the metallic reflective mirror layer equals to the remained light intensity ratio in the resonant cavity, and by means of critical coupling of a resonant cavity, all the incident lights are locked in the cavity between the metallic reflective mirror layer and the dielectric reflective mirror layer so as to achieve one hundred percent absorption.

In one preferred embodiment, a buried oxide layer is further disposed between the metallic reflective mirror layer and the light absorbent layer.

In one preferred embodiment, the metallic reflective mirror layer can be positioned flat between the light absorbent layer and the silicon substrate.

In one preferred embodiment, the dielectric reflective mirror layer is a distributed Bragg reflector (BR).

In one preferred embodiment, the metallic reflective mirror layer has a diameter greater than the dielectric reflective mirror layer.

In one preferred embodiment, the n-type epitaxial silicon layer of light absorbent layer has thickness of about 200˜300 nm.

In one preferred embodiment, the reflectance ratio of the dielectric reflective mirror layer to the metallic reflective mirror layer equals to the remained light intensity ratio in the resonant cavity; and by means of reaching critical coupling of a resonant cavity according to the following equation, all incident lights are locked in the cavity between the metallic reflective mirror layer and the dielectric reflective mirror layer as the light locking mode:

r_{D}=r_{M}e⁻ⁿ^{ᵢ}^{k}^{₀}^{2d},

wherein r_{M} is the reflectance of the metallic reflective mirror layer; and r_{D} is the reflectance of the dielectric reflective minor layer.

In one preferred embodiment, a p-type ohmic contact layer is further disposed in a part of the p-type amorphous silicon layer.

In one preferred embodiment, the p-type ohmic contact layer further includes a p-type metallic conductive layer.

In one preferred embodiment, an n-type ohmic contact layer is further disposed in a part of the n-type epitaxial silicon layer.

### BRIEF DESCRIPTION OF THE DRAWINGS

FIG. 1 is a schematic view of structure of a high-efficiency bandwidth product germanium photodetector according to invention.

FIG. 2 is a schematic view of a high-efficiency bandwidth product germanium photodetector at light locking mode when in use according to invention.

FIG. 3 is a schematic view of a high-efficiency bandwidth product germanium photodetector according to another embodiment of the invention.

FIG. 4 is a schematic view of an optical coupling device able to be integrated with a conventional photodetector.

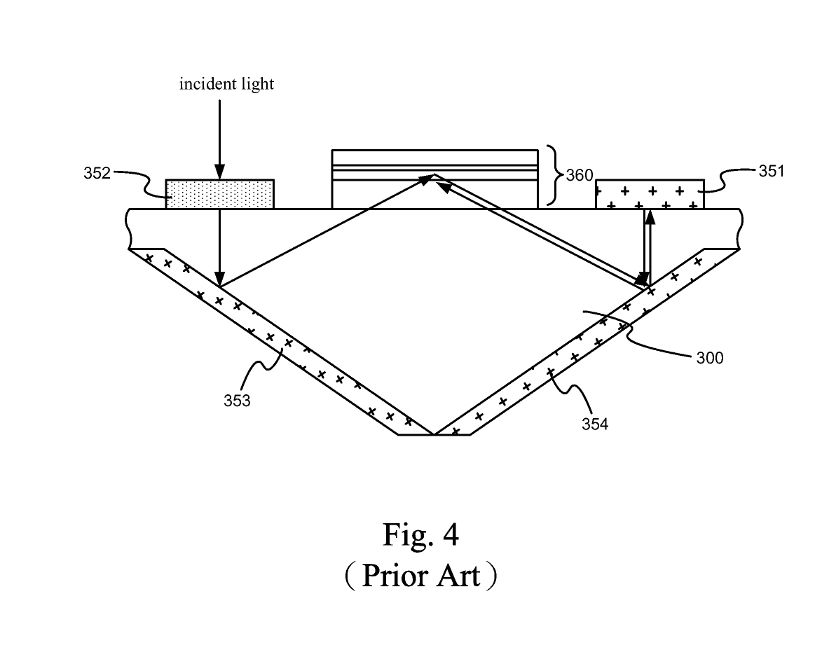

### DETAILED DESCRIPTION OF THE PREFERRED EMBODIMENTS

The aforementioned illustrations and following detailed descriptions are exemplary for the purpose of further explaining the scope of the present invention. Other objectives and advantages related to the present invention will be illustrated in the subsequent descriptions and appended tables.

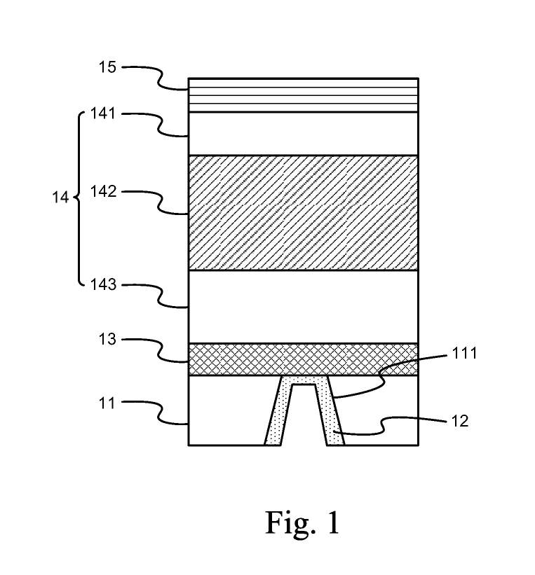

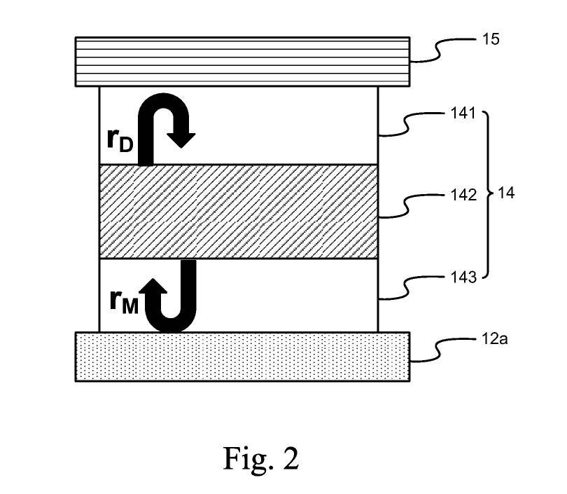

FIG. 1 is a schematic view of structure of a high-efficiency bandwidth product germanium photodetector according to invention. FIG. 2 is a schematic view of a high-efficiency bandwidth product germanium photodetector at light locking mode when in use according to invention. As shown, the high-efficiency bandwidth product germanium photodetector according to invention at least includes a silicon substrate 11, a metallic reflective mirror layer 12, a buried oxide layer 13, a light absorbent layer 14 and a dielectric reflective minor layer 15.

The silicon substrate 11 has an opening-down three-sided groove 111.

The metallic reflective mirror layer 12 is disposed along an internal periphery of the opening-down three-sided groove 111 of the silicon substrate 11, and therefore has the opening-down three-sided structure conform to the opening-down three-sided groove 111.

The buried oxide layer 13 is disposed on the metallic reflective mirror layer 12.

The light absorbent layer 14 is provided at the top of the buried oxide layer 13, and has a pin structure having a p-type amorphous silicon layer (a-Si) 141, an i-type germanium layer 142 and an n-type epitaxial silicon layer (Epi-Si) 143.

The dielectric reflective mirror layer 15 is disposed on the light absorbent layer 14. With the use of the metal reflective mirror layer 12, a resonator structure which allows the light to reflect several times is formed.

The above metallic reflective minor layer 12 has a diameter greater than the dielectric reflective mirror layer 15, and can be positioned flat, like the metallic reflective mirror layer 12a shown in FIG. 2.

By means of reaching critical coupling of a resonant cavity according to the following equation, the reflectance of the metallic reflective mirror layer 12 and the dielectric reflective mirror layer 15 equals to the absorption rate of the resonant cavity, so that all the incident lights are locked in the cavity between the metallic reflective mirror layer 12 and the dielectric reflective mirror layer 15 so as to reach one hundred percent absorption as the light locking mode shown in FIG. 2. The equation is

r_{D}=r_{M}e⁻ⁿ^{ᵢ}^{k}^{₀}^{2d},

Wherein r_{M} is the reflectance of the metallic reflective mirror layer; and r_{D} is the reflectance of the dielectric reflective mirror layer.

Thereby, such a configuration constitutes a new high-efficiency bandwidth product germanium photodetector.

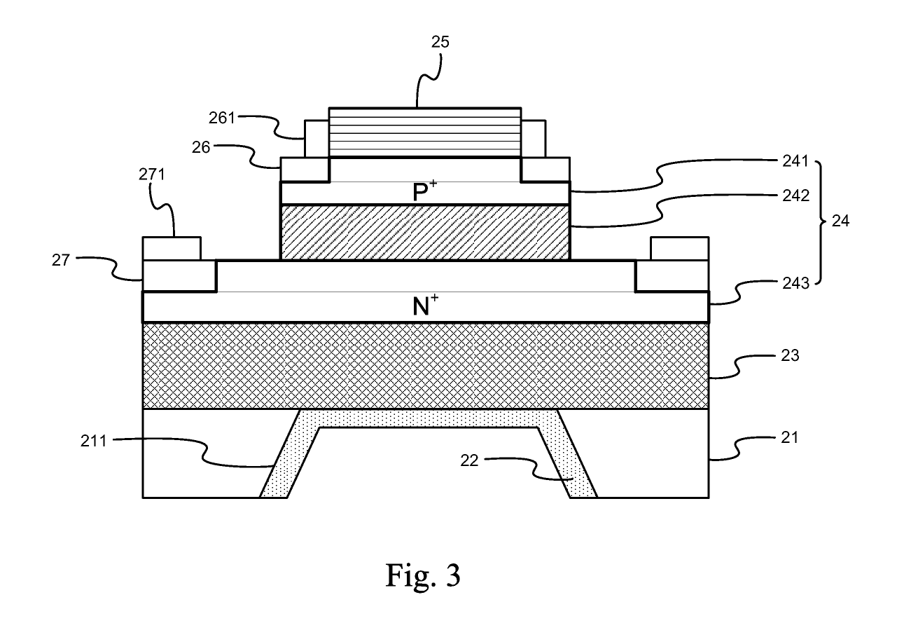

FIG. 3 is a schematic view of a high-efficiency bandwidth product germanium photodetector according to another embodiment of the invention. As shown, the high-efficiency bandwidth product germanium photodetector according to the invention includes a silicon substrate 21, a metallic reflective mirror layer 22, a buried oxide layer 23, a light absorbent layer 24, the dielectric reflective mirror layer 25, a p-type ohmic contact layer 26, and an n-type ohmic contact layer 27. The photodetector of the present invention optionally further includes a p-type metallic conductive layer 261 and an n-type metallic conductive layer 271 so as to connect to the light absorbent layer 24.

The silicon substrate 21 has an opening-down three-sided groove 211.

The metallic reflective mirror layer 22 is disposed along an internal periphery of the opening-down three-sided groove 211 of the silicon substrate 21, and therefore has the opening-down three-sided structure conform to the opening-down three-sided groove 211.

The buried oxide layer 23 is disposed on the metallic reflective mirror layer 22, and has a thickness of about 2˜3 μm.

The light absorbent layer 24 is disposed on the top of the buried oxide layer 23, and has a pin structure including a p-type amorphous silicon layer 241, an i-type germanium layer 242 and a n-type epitaxial silicon layer 243 having thickness of about 200˜300 nm.

The dielectric reflecting mirror layer 25 is a distributed Bragg reflector (DBR), and is disposed on the light absorbent layer 24. With the use of the metallic reflective mirror layer 22, a resonant cavity which allows the lights to reflect several times is formed.

The p-type ohmic contact layer 26 is a p-type doped nickel silicide (NiSi) as a p-type electrode. The p-type ohmic contact layer 26 is disposed in a part of the p-type amorphous silicon layer 241. On the p-type ohmic contact layer 26, a p-type metallic conductive layer 261 which can be aluminum metal for example is further included.

The n-type ohmic contact layer 27 can be n-type doped nickel silicide as n-type electrode. The n-type ohmic contact layer 27 is disposed in a part of the n-type amorphous silicon layer 243. On the n-type ohmic contact layer 27, an n-type metallic conductive layer 271 which can be aluminum metal for example is further included.

With the use of the aforementioned equation, the above configuration allows the reflectance ratio of the dielectric reflective mirror layer to the metallic reflective mirror layer equals to the remained light intensity ratio in the resonant cavity. All incident lights can be completely obstructed in the cavity between the metallic reflective mirror layer and the dielectric reflective mirror layer to reach a critical coupling which means 100% absorption efficiency can be achieved without light leakage. Thus on the basis of the critical coupling, the trade-off between bandwidth and efficiency can be broken through to reach high responsivity and high bandwidth up to 50 GHz in order to increase the light-switch-to-electro absorption efficiency.

In summary, the present invention provides to a high-efficiency bandwidth product germanium photodetector which can effectively improve the shortcomings of the prior art. By means of etching the opening-down three-sided groove on the silicon substrate, plating the metallic reflective mirror layer conform to the inner periphery of the opening-down three-sided groove, adding a dielectric reflective mirror layer onto the photodetector, sandwiching a p-i-n type or other types light absorbent layer between the metallic reflective mirror layer and the dielectric reflective mirror layer, the critical coupling of resonant cavity can be formed with the use of the above equation. All the incident lights can be completely obstructed in the cavity between the metallic reflective mirror layer and the dielectric reflective mirror layer to reach a critical coupling which means 100% absorption efficiency can be achieved without light leakage. Thus on the basis of the critical coupling, the trade-off between bandwidth and efficiency can be broken through to reach high responsivity and high bandwidth up to 50 GHz by decreasing the germanium layer thickness without sacrificing the light-switch-to-electro absorption efficiency. This makes the invention more progressive and more practical in use which complies with the patent law.

The descriptions illustrated supra set forth simply the preferred embodiments of the present invention; however, the characteristics of the present invention are by no means restricted thereto. All changes, alternations, or modifications conveniently considered by those skilled in the art are deemed to be encompassed within the scope of the present invention delineated by the following claims.

1. A high-efficiency bandwidth product germanium photodetector comprising:
a silicon substrate, having an opening-down three-sided groove;
a metallic reflective mirror layer; disposed along an internal periphery of the opening-down three-sided groove of the silicon substrate, and therefore having the opening-down three-sided structure conform to the opening-down three-sided groove;
a light absorbent layer, disposed on the metallic reflective mirror layer and having a pin structure which includes a p-type amorphous silicon layer (a-Si), an i-type germanium layer and an n-type epitaxial silicon layer (Epi-Si); and
a dielectric reflective mirror layer, disposed on the absorbent layer, wherein with the use of the metal reflective mirror layer, a resonator structure which allows the light to reflect several times is formed;
wherein the reflectance ratio of the dielectric reflective mirror layer to the metallic reflective mirror layer equals to the remained light intensity ratio in the resonant cavity, and by means of critical coupling of a resonant cavity, all the incident lights are locked in the cavity between the metallic reflective mirror layer 1 and the dielectric reflective mirror layer so as to achieve one hundred percent absorption.

2. The photodetector of claim 1,
wherein a buried oxide layer is further disposed between the metallic reflective mirror layer and the light absorbent layer.

3. The photodetector of claim 1,
wherein the metallic reflective mirror layer can be positioned flat between the light absorbent layer and the silicon substrate.

4. The photodetector of claim 1,
wherein the dielectric reflective mirror layer is a distributed Bragg reflector (BR).

5. The photodetector of claim 1,
wherein the metallic reflective mirror layer has a diameter greater than the dielectric reflective mirror layer.

6. The photodetector of claim 1,
wherein the n-type epitaxial silicon layer of the light absorbent layer has thickness of about 200˜300 nm.

7. The photodetector of claim 1, wherein the reflectance ratio of the dielectric reflective mirror layer to the metallic reflective mirror layer equals to the remained light intensity ratio in the resonant cavity; and by means of reaching critical coupling of a resonant cavity according to the following equation, all incident lights are locked in the cavity between the metallic reflective mirror layer and the dielectric reflective mirror layer as the light locking mode:
R_{D}=r_{M}e⁻ⁿ^{ᵢ}^{k}^{₀}^{2d},
wherein r_{M} is the reflectance of the metallic reflective mirror layer; and r_{D} is the reflectance of the dielectric reflective mirror layer.

8. The photodetector of claim 1,
wherein a p-type ohmic contact layer is further disposed in a part of the p-type amorphous silicon layer.

9. The photodetector of claim 8,
wherein the p-type ohmic contact layer further includes a p-type metallic conductive layer.

10. The photodetector of claim 1,
wherein an n-type ohmic contact layer is further disposed in a part of the n-type epitaxial silicon layer.
